(19) United States
(12) Patent Application Publication
(10) Pub. No.: US 2011/0103171 A1
(43) Pub. Date: May 5, 2011

(54) SEMICONDUCTOR MEMORY APPARATUS

(75) Inventor: Heat Bit Park, Ichon-si (KR)

(73) Assignee: Hynix Semiconductor Inc., Ichon-si (KR)

(21) Appl. No.: 12/650,795

(22) Filed: Dec. 31, 2009

(30) Foreign Application Priority Data
Oct. 30, 2009 (KR) 10-2009-0104385

(51) Int. Cl. G11C 8/00; G11C 7/00

(52) U.S. Cl. 365/230.03; 365/198

(57) ABSTRACT

A semiconductor memory apparatus is provided. The semiconductor memory apparatus includes: first and second memory banks located at a predetermined distance from each other; a common column selection signal transmission line configured to transfer a column selection signal for controlling data access to corresponding memory cells in the first and second memory banks; and a column selection signal repeater inserted in the common column selection signal transmission line, and configured to transfer the column selection signal for controlling data access to the memory cell in the first memory bank. A transmission path of the column selection signal for controlling data access to the memory cell in the first memory bank is longer than that of the column selection signal for controlling data access to the memory cell in the second memory bank.

### CROSS-REFERENCE TO RELATED APPLICATION

The present application claims priority under 35 U.S.C. §119(a) to Korean Patent Application No. 10-2009-0104385, filed on Oct. 30, 2009, in the Korean Intellectual Property Office, which is incorporated herein by reference in its entirety as if set forth in full.

### BACKGROUND

1. Technical Field

Various aspects of the present disclosure generally relate to a semiconductor memory apparatus, and more particularly, to a technology which controls a slew rate of a column selection signal.

2. Related Art

A semiconductor memory apparatus has an internal memory area divided into multiple memory banks. The multiple memory banks are selectively enabled by a bank address signal. Generally, the arrangement structure of multiple memory banks and internal circuits is determined by the operational performance and space efficiency.

FIG. 1 illustrates an internal structure of a typical semiconductor memory apparatus.

Referring to FIG. 1, a typical semiconductor memory apparatus 1 comprises first memory banks BANK0_0 and BANK0_1 110 and 120 second memory banks BANK1_0 and BANK1_1 210 and 220, first to fourth column selection control units 111, 121, 211 and 221, first to fourth data write units 112, 122, 212 and 222, and first to fourth data read units 113, 123, 213 and 223.

For reference, the first memory banks BANK0_0 and BANK0_1 110 and 120 are divided into a first sub bank 110 and a second sub bank 120, and the second memory banks BANK1_0 and BANK1_1 210 and 220 are divided into a third sub bank 210 and a fourth sub bank 220. The memory banks which are each selectively enabled by a bank address signal may be physically divided into multiple sub banks.

Circuits configured to control access to row areas of the memory banks are provided in row control areas X LOGIC 311 and 312. Drivers and repeaters for various internal signals are provided in a cross area XY CROSS 320.

The first data write unit 112 is configured to transfer write data to the first sub bank 110, and the first data read unit 113 is configured to sense and amplify read data transferred from the first sub bank 110. The second data write unit 122 is configured to transfer write data to the second sub bank 120, and the second data read unit 123 is configured to sense and amplify read data transferred from the second sub bank 120. The third data write unit 212 is configured to transfer write data to the third sub bank 210, and the third data read unit 213 is configured to sense and amplify read data transferred from the third sub bank 210. The fourth data write unit 222 is configured to transfer write data to the fourth sub bank 220, and the fourth data read unit 223 is configured to sense and amplify read data transferred from the fourth sub bank 220.

Meanwhile, each of the first to fourth column selection control units 111, 121, 211 and 221 is configured to control access to each column area of the first memory banks BANK0_0 and BANK0_1 110 and 120 and the second memory banks BANK1_0 and BANK1_1 210 and 220, respectively. The basic operations of the first to fourth column selection control units 111, 121, 211 and 221 are identical to one another. Therefore, the internal operation of the first column selection control unit 111 and the related internal circuits thereof will be described in detail as a representative example.

Column selection signals YI<0> to YI<i> generated by the first column selection control unit 111 control data access to the corresponding memory cell in the first sub bank 110 located within the first memory banks. The column selection signals YI<0> to YI<i> may be transferred through transmission lines to the first sub bank 110. For example, when a specific column selection signal YI<k> is activated, data access to the corresponding memory cell is performed. Thus, in the data read mode, the first data read unit 113 senses and amplifies read data which is transferred from the corresponding memory cell. In the data write mode, the first data write unit 112 transfers write data to the corresponding memory cell.

As described above, the typical semiconductor memory apparatus 1 comprises the column selection control unit provided in each memory bank. In the above example, the column selection control unit in each sub bank of the memory bank. Such a structure needs a large chip area when the column selection control units are arranged. Therefore, there is a need for technology which solves the above-described problems, without degrading the performance of the access to the column area.

### SUMMARY

Accordingly, there is a need for an improved semiconductor memory apparatus that overcomes the problems discussed above. To attain the advantages and in accordance with the purposes of the invention, as embodied and broadly described herein, various aspects of the invention may provide a semiconductor memory apparatus comprises: first and second memory banks located at a predetermined distance from each other; a common column selection signal transmission line configured to transfer a column selection signal for controlling data access to corresponding memory cells in the first and second memory banks; and a column selection signal repeater inserted in the common column selection signal transmission line, and configured to transfer the column selection signal for controlling data access to the memory cell in the first memory bank. A transmission path of the column selection signal for controlling data access to the memory cell in the first memory bank is longer than that of the column selection signal for controlling data access to the memory cell in the second memory bank.

In another aspect of the present disclosure, a semiconductor memory apparatus may comprise: first and second memory banks located at a predetermined distance from each other in a first direction; a common column selection control unit located at an outside region in the first and second memory banks in the first direction, and configured to commonly control access to column areas in the first and second memory banks; a common column selection signal transmission line configured to transfer a column selection signal for controlling data access to corresponding memory cells in the first and second memory banks, the column selection signal being generated by the common column selection control unit; and a column selection signal repeater inserted in the common column selection signal transmission line, and configured to transfer the column selection signal for controlling data access to the memory cell in the first memory bank. A transmission path of the column selection signal for controlling data access to the memory cell in the first memory bank is longer than that of the column selection signal for controlling data access to the memory cell in the second memory bank.

### BRIEF DESCRIPTION OF THE DRAWINGS

The accompanying drawings, which are incorporated in and constitute a part of this specification, illustrate various embodiments consistent with the invention and, together with the description, serve to explain the principles of the invention.

FIG. 1 illustrates an exemplary internal structure of a typical semiconductor memory apparatus.

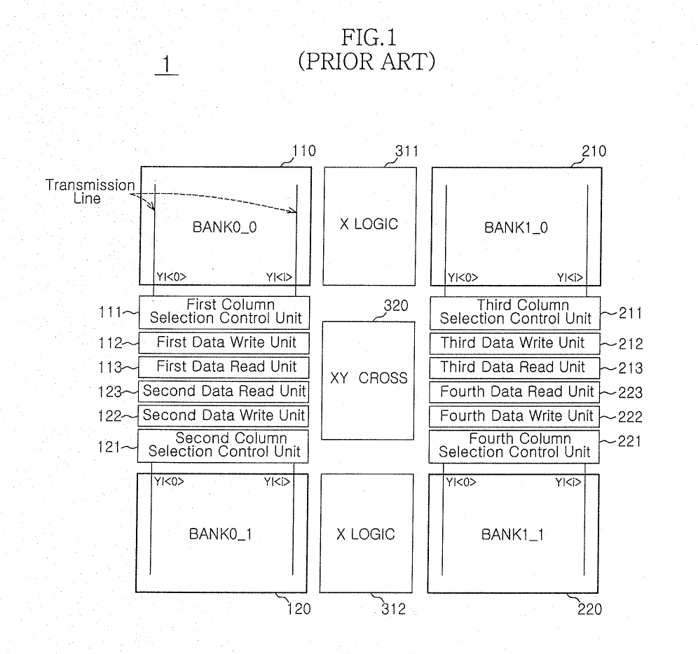

FIG. 2 illustrates an internal structure of a semiconductor memory apparatus according to a first aspect.

FIG. 3 is a detailed configuration diagram of the semiconductor memory apparatus illustrated in FIG. 2.

FIG. 4 illustrates an internal structure of a semiconductor memory apparatus according to a second aspect.

FIG. 5 illustrates a simulation result of the semiconductor memory apparatus according to the aspects.

### DETAILED DESCRIPTION

Reference will now be made in detail to the exemplary embodiments consistent with the present disclosure, examples of which are illustrated in the accompanying drawings. Wherever possible, the same reference characters will be used throughout the drawings to refer to the same or like parts.

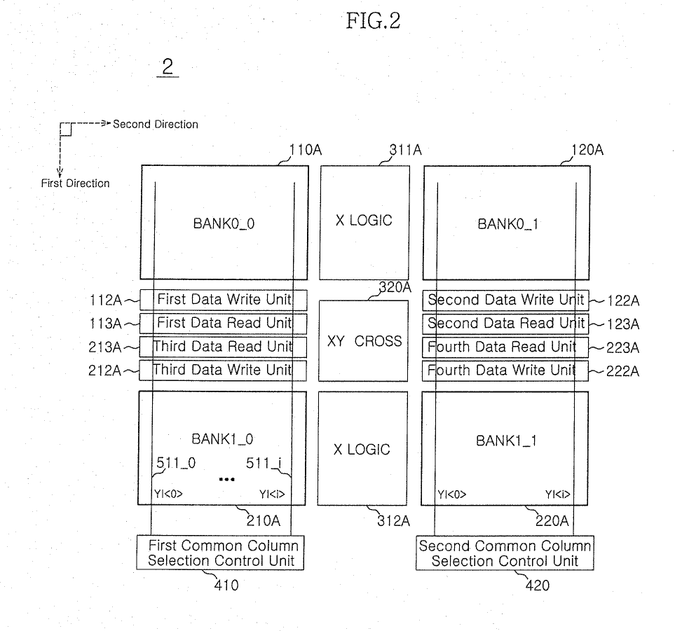

FIG. 2 illustrates an internal structure of a semiconductor memory apparatus according to one embodiment of the invention.

The semiconductor memory apparatus 2 according to this aspect comprises only components for illustrating the proposed technical ideas. Those skilled in the art will readily understand that the semiconductor memory apparatus 2 may include other components as well.

Referring to FIG. 2, the semiconductor memory apparatus 2 comprises first memory banks BANK0_0 and BANK0_1 110A and 120A, second memory banks BANK1_0 and BANK1_1 210A and 220A, first and second common column selection control units 410 and 420, first to fourth data write units 112A, 122A, 212A, and 222A, and first to fourth data read units 113A, 123A, 213A, and 223A.

For reference, the first memory banks BANK0_0 and BANK0_1 110A and 120A are divided into first and second sub banks 110A and 120A, and the second memory banks BANK1_0 and BANK1_1 210A and 220A are divided into third and fourth sub banks 210A and 220A. As such, the memory banks which are each to selectively activated by a bank address signal may be arranged so as to be physically divided into multiple sub banks.

Now, the detailed configuration and the main operation of the semiconductor memory apparatus configured in the manner described above will be explained.

The first memory banks BANK0_0 and BANK0_1 110A and 120A and the second memory banks BANK1_0 and BANK1_1 210A and 220A are located at a predetermined distance from each other respectively in a first direction. Circuits configured to control access to row areas of the memory banks are provided in row control areas, X LOGIC 311A and 312A, and drivers and repeaters for various internal signals are provided in a cross area XY CROSS 320A. The first row control area 311A is located between the first sub bank 110A and the second sub bank 120A in a second direction, and the second row control area 312A is located between the third sub bank 210A and the fourth sub bank 220A in the second direction. The cross area XY CROSS 320A is located between the first row control area 311A and the second row control area 312A in the first direction. The first and second directions are perpendicular to each other.

The first data write unit 112A is configured to transfer write data to the first sub bank 110A, and the first data read unit 113A is configured to sense and amplify read data transferred from the first sub bank 110A. Likewise, the second data write unit 122A is configured to transfer write data to the second sub bank 120A, and the second data read unit 123A is configured to sense and amplify read data transferred from the second sub bank 120A. The third data write unit 212A is also configured to transfer write data to the third sub bank 210A, and the third data read unit 213A is configured to sense and amplify read data transferred from the third sub bank 210A. The fourth data write unit 222A is configured to transfer write data to the fourth sub bank 220A, and the fourth data read unit 223A is configured to sense and amplify read data transferred from the fourth sub bank 220A.

The first common column selection control unit 410 is configured to control access to column areas in the first sub bank 110A in the first memory banks and the third sub bank 210A of the second memory banks. The second common column selection control unit 420 may be configured to control access to column areas of the second sub bank 120A in the first memory banks and the fourth sub bank 220A of the second memory banks. For example, the first and second common column selection control unit 410 and 420 commonly control the first and second memory banks. The basic operations of the first and second common column selection units 410 and 420 are identical. Therefore, the internal operation of the first common column selection unit 410 and the related internal circuits thereof will be described in detail, but only as a representative example that the disclosure is not limited to.

Column selection signals YI<0> to YI<i> generated by the first common column selection control unit 410 control data access to the corresponding memory cell in the first sub bank 110A of the first memory banks and the third sub bank 210A of the second memory banks. The column selection signals YI<0> to YI<i> are transferred to the first sub bank 110A and the third sub bank 210A through common column selection signal transmission lines 511_0 to 511_i. As described above, multiple memory banks are selectively activated by a bank address signal. Therefore, although a specific column selection signal YI<k> is commonly transferred to the first sub bank 110A of the first memory banks and the third sub bank 210A of the second memory banks through the common column selection signal transmission lines 511_0 to 511_i, the semiconductor memory apparatus can perform a normal operation.

When the first sub bank 110A of the first memory banks and the specific column selection signal YI<k> are activated, data access to the corresponding memory cell in the first sub bank 110A is allowed. Therefore, the first data read unit 113A senses and amplifies read data transferred from the corresponding memory cell in the data read mode. The first data write unit 112A transfers write data to the corresponding memory cell in the data write mode. For reference, the column selection signal is a signal which is activated in response to a column address signal.

When the third sub bank 210A of the second memory banks and the specific column selection signal YI<k> are activated, data access to the corresponding memory cell of the third sub bank 210A is allowed. Therefore, the third data read unit 213A senses and amplifies read data transferred from the corresponding memory cell in the data read mode. The third data write unit 212A transfers write data to the corresponding memory cell in the data write mode.

The semiconductor memory apparatus 2 configured in such a manner commonly controls the access to the column areas in the first and second memory banks through the common column selection control unit. Therefore, an area for disposing the circuits is not required.

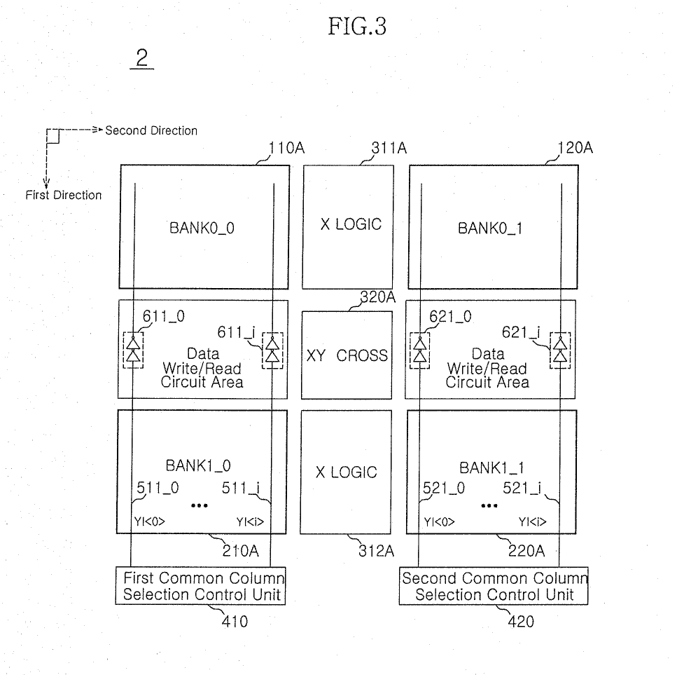

FIG. 3 is a detailed configuration diagram of the semiconductor memory apparatus of FIG. 2.

Referring to FIG. 3, the semiconductor memory apparatus 2 comprises the first memory banks BANK0_0 and BANK0_1 110A and 120A, the second memory banks BANK1_0 and BANK1_1 210A and 220A, the first and second common column selection control units 410 and 420, the common column selection signal transmission lines 511_0 to 511_i and 521_0 to 521_i, and column selection signal repeaters 611_0 to 611_i and 621_0 to 621_1.

For reference, the first memory banks BANK0_0 and BANK0_1 110A and 120A are divided into first and second sub banks 110A and 120A, and the second memory banks BANK1_0 and BANK1_1 210A and 220A are divided into third and fourth sub banks 210A and 220A. The memory banks which are selectively activated by a bank address signal may be physically divided into multiple sub banks.

The first memory bank BANK0_0 and BANK0_1 110A and 120A and the second memory banks BANK1_0 and BANK1_1 210A and 220A are located at a predetermined distance from each other in the first direction.

The first common column selection control unit 410 is located in an outer region of the first sub bank 110A of the first memory banks and the third sub bank 210A of the second memory banks in the first direction. The second common column selection control unit 420 is located at an outer region of the second sub bank 120A of the first memory banks and the fourth sub bank 220A of the second memory banks in the first direction.

The common column selection signal transmission lines 511_0 to 511_i and 521_0 to 521_i are configured to transfer column selection signals YI<0> to YI<i> to control data access to the corresponding memory cells in the first and second memory banks. The column selection signals YI<0> to YI<i> are signals generated by the first and second common column selection control units 410 and 420.

The column selection signal repeaters 611_0 to 611_i and 621_0 to 621_i are inserted in the common column selection signal transmission lines 511_0 to 511_i and 521_0 to 521_i, respectively, and configured to transfer the corresponding column selection signal for controlling data access to the memory cells in the first memory banks. Each of the column selection signal repeaters may be configured with one or more buffers or inverters.

To clarify the technical ideas proposed in this aspect, the following descriptions will focus on an access operation that reaches to the first sub bank 110A of the first memory banks and the third sub bank 210A of the second memory banks. The description of an access operation to the second sub bank 120A of the first memory banks and the fourth sub bank 220A of the second memory banks will be omitted to avoid a duplicate description

When the first sub bank 110A of the first memory banks and a specific column selection signal YI<k> are activated, data in the corresponding memory cell of the first sub bank 110A is accessible. Furthermore, when the third sub bank 210A of the second memory banks and the specific column selection signal YI<k> are activated, data in the corresponding memory cell of the third sub bank 210A is accessible. At this time, the column selection signal YI<k> is transferred through a common column selection signal transmission line. In other words, the column selection signal that controls data access to the memory cell in the first sub bank 110A of the first memory banks and the column selection signal that controls the data access to the memory cell of the third sub bank 210A of the second memory banks are commonly transferred through the common column selection signal transmission line.

At this time, the transmission path of the column selection signal for controlling the data access to the memory cell in the first sub bank 110A of the first memory banks is longer than that of the column selection signal for controlling the data access to the memory cell of the third sub bank 210A of the second memory banks. Therefore, when the column selection signal for controlling the data to access to the memory cell in the first sub bank 110A of the first memory banks is transferred through the common column selection signal transmission line, the slew rate of the column selection signal may decrease due to a load value of the common column selection signal transmission line, such as capacitance or the like. In this is aspect, however, the column selection signal for controlling the data access to the memory cell in the first sub bank 110A of the first memory banks is transferred through a column selection signal repeater 611_k, the slew rate of the column selection signal is compensated for. Therefore, although the length of the common column selection signal transmission line is large, it is possible to suppress a variation in the slew rate of the column selection signal. Furthermore, a variation in the timing of data access to the corresponding memory cells in the first and second memory banks is suppressed.

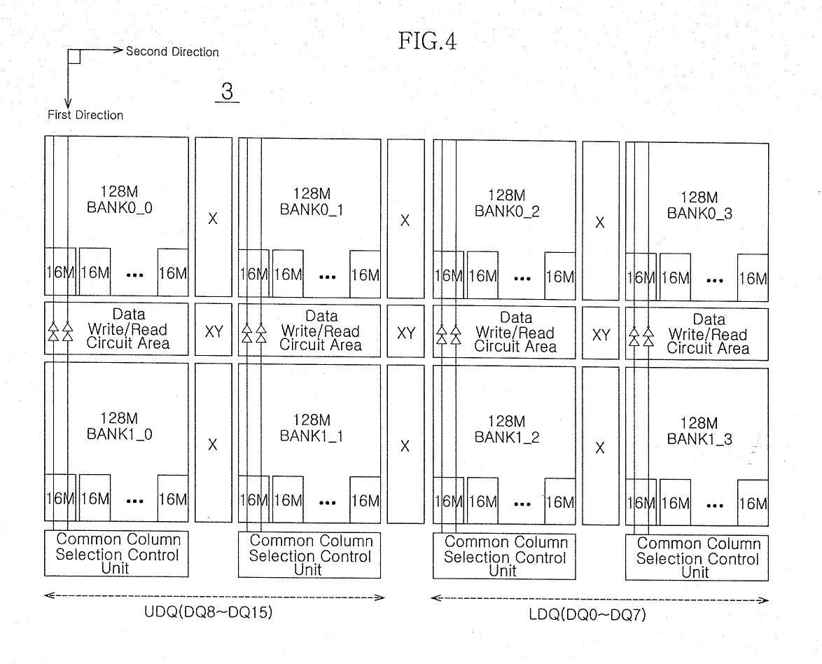

FIG. 4 illustrates an internal structure of a semiconductor memory apparatus according to what may be a second aspect.

Referring to FIG. 4, the semiconductor memory apparatus 3 according to the second aspect comprises first memory banks BANK0_0 to BANK0_3, second memory banks BANK1_0 to BANK1_3, common column selection control units, and so on. In other words, the semiconductor memory apparatus 3 according to the second aspect is implemented by reflecting the technical ideas applied to the semiconductor memory apparatus 2 according to the first aspect. The first memory banks BANK0_0 to BANK0_3 and the second memory banks BANK1_0 to BANK1_3, respectively, are divided into four sub banks.

The first memory banks BANK0_0 to BANK0_3 and the second memory banks BANK1_0 to BANK1_3 are a predetermined distance from each other in a first direction. Multiple sub banks is composing the first memory bank BANK0_0 to BANK0_3 are a predetermined distance from each other in a second direction, and multiple sub banks composing the second memory bank BANK1_0 to BANK1_3 are also a predetermined distance from each other in the second direction. The first and second directions are perpendicular to each other.

The semiconductor memory apparatus 3 according to the second aspect comprises pads which are divided into a first data input/output pad group UDQ and a second data input/output pad group LDQ. Such an arrangement of the pads can distribute arrangements of global transmission lines. Therefore, the arrangement of the pads has an advantage in area.

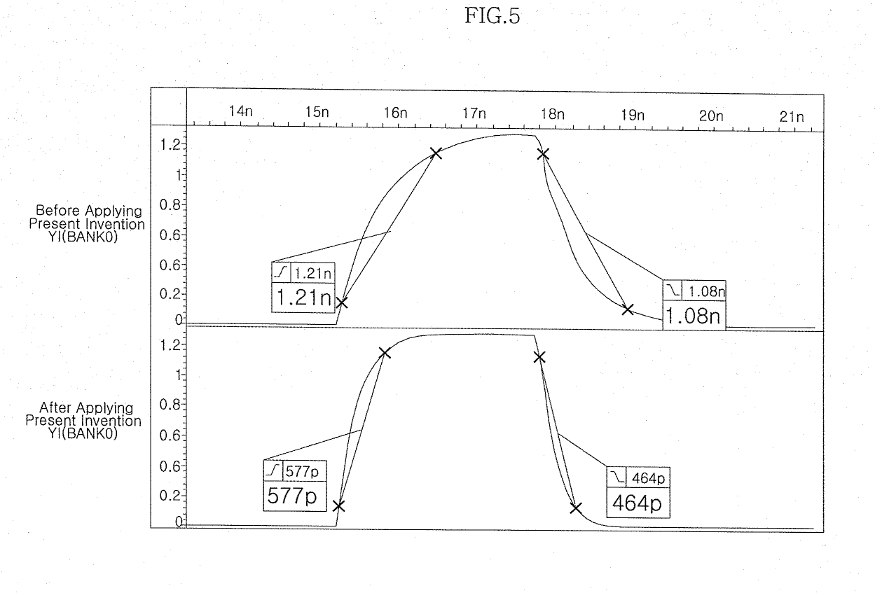

FIG. 5 illustrates a simulation result of the semiconductor memory apparatus according to the aspects.

Referring to FIG. 5, the slew rate of a column selection signal YI before the present disclosure is applied is comparable to the rate after the present disclosure is applied. In other words, when the column selection signal repeater is used to transfer the column selection signal YI, it is possible to suppress a decrease in slew rate of the column selection signal YI even with a long common column selection signal transmission line.

In the above-described semiconductor memory apparatus according to the aspects, when a column selection signal is transferred to multiple memory banks through a common column selection signal transmission line, a variation in slew rate of the is column selection signal can be suppressed even with a long common column selection signal transmission line. In other words, when the column selection signal is transferred through the common column selection signal transmission line to the first and second memory banks, the slew rate of the column selection signal does not vary in proportion to a length difference in transmission path of the column selection signal. Therefore, a variation in timing of data access to the corresponding memory cells in the first and second memory banks decreases.

While certain aspects have been described above, it will be understood to those skilled in the art that the aspects described are by way of example only. Accordingly, the apparatus described herein should not be limited based on the described aspects. Rather, the apparatus described herein should only be limited in light of the claims that follow when taken in conjunction with the above description and accompanying drawings.

What is claimed is:

1. A semiconductor memory apparatus comprising:
first and second memory banks located at a predetermined distance from each other;
a common column selection signal transmission line configured to transfer a column selection signal for controlling data access to corresponding memory cells in the first and second memory banks; and
a column selection signal repeater inserted in the common column selection signal transmission line, and configured to transfer the column selection signal for controlling data access to the memory cell in the first memory bank,
wherein a transmission path of the column selection signal for controlling data access to the memory cell in the first memory bank is longer than that of the column selection signal for controlling data access to the memory cell in the second memory bank.

2. The semiconductor memory apparatus of claim 1,
wherein the column selection signal is activated in response to a column address signal.

3. The semiconductor memory apparatus of claim 1,
wherein each of the first and second memory banks is selectively activated in response to a bank address signal.

4. A semiconductor memory apparatus comprising:
first and second memory banks located at a predetermined distance from each other in a first direction;
a common column selection control unit located at an outside region in the first and second memory banks in the first direction, and configured to commonly control access to column areas in the first and second memory banks;
a common column selection signal transmission line configured to transfer a column selection signal for controlling data access to corresponding memory cells in the first and second memory banks, the column selection signal being generated by the common column selection control unit; and
a column selection signal repeater inserted in the common is column selection signal transmission line, and configured to transfer the column selection signal for controlling data access to the memory cell in the first memory bank,
wherein a transmission path of the column selection signal for controlling data access to the memory cell in the first memory bank is longer than that of the column selection signal for controlling data access to the memory cell in the second memory bank.

5. The semiconductor memory apparatus of claim 4,
wherein the column selection signal is activated in response to a column address signal.

6. The semiconductor memory apparatus of claim 4,
wherein each of the first and second memory banks is selectively activated in response to a bank address signal.
